(19) United States
(12) Patent Application Publication
(10) Pub. No.: US 2022/0181553 A1
(43) Pub. Date: Jun. 9, 2022

(54) RAPID PHOTONIC ANNEALING OF TRANSPARENT CONDUCTING OXIDE FILMS

(71) Applicant: The Board of Trustees of the University of Alabama, Tuscaloosa, AL (US)

(72) Inventor: Dawen Li, Tuscaloosa, AL (US)

(21) Appl. No.: 17/537,664

(22) Filed: Nov. 30, 2021

Related U.S. Application Data
(60) Provisional application No. 63/121,591, filed on Dec. 4, 2020.

(51) Int. Cl. H01L 51/00; H01L 31/0224; H01L 33/42

(52) U.S. Cl. CPC H01L 51/0021; H01L 2933/0016; H01L 33/42; H01L 31/022475

(57) ABSTRACT

Methods of annealing and/or sintering a transparent conductive oxide (TCO) film disclosed, and wherein the TCO film comprises indium tin oxide film (ITO), fluorine-doped tin film (FTO), indium doped zinc oxide (IZO), or aluminum-doped zinc oxide (AZO). Such methods involve irradiating the TCO film with a light source and where the annealing and/or sintering is selective to the TCO film.

### CROSS-REFERENCE TO RELATED APPLICATIONS

This application claims benefit of U.S. Provisional Application No. 63/121,591, filed Dec. 4, 2020, the content of which is incorporated herein by reference in its whole entirety.

### FIELD

The present disclosure relates generally to treatment of transparent conducting oxide films. More specifically, the present disclosure relates to methods of making multi-layer structures used in solar cells or light-emitting diodes. Even more particularly, the current disclosure relates to the rapid and layer-specific photonic treatment of the transparent conductive oxide films using ultraviolet (UV) light-emitting diodes (LEDs) to facilitate fabrication of the multi-layer structures.

### BACKGROUND

Solar cells or light-emitting devices include a layer of transparent conductive oxide (TCO) material forming a window for light to pass through to or from active layers. TCO materials generally include optically transparent and electrically conductive materials. To attain high-quality TCO films with high transmittance and low sheet resistance (i.e., high conductivity), the solution-processed TCO films are often annealed to improve their crystallinity. However, the conventional annealing methods, such as the use of hotplates or ovens, demand high temperatures and lengthy annealing times to obtain the desired crystallinity for conductivity and transparency. High annealing temperature requirements by thermal annealing will damage the underlying layers of TCO film, particularly flexible substrate and perovskite and/or organic thin film, because traditional hotplate annealing heats all the stacking layers simultaneously. To attain high-quality TCO films without damaging underlying stacking layers, rapid and layer-specific annealing is desired.

The solar cells and light-emitting devices are constructed of multiple layers deposited on a substrate. Because of the limited temperature tolerance of flexible substrates, for example, and other layers such as the perovskite active layer or organic-based active layer, using a hotplate or oven for annealing of TCO films is problematic as it is not layer-specific and can damage these underlying layers. To avoid damage, often, lower temperatures are used. Such thermal heating methods can also result in temperature reconciliation of all stacking layers due to thermal conduction, thereby damaging underlying layers if the required annealing temperatures of TCO films are much higher than withstanding temperatures of other underlying layers. Such low annealing temperatures cause poor crystallinity of the transparent conductive oxides, consequently low transparency and high sheet resistance.

It is understood that annealing with the methods disclosed herein exhibits advantages over the current technology. For example, hotplate annealing at high temperatures (for example, 500° C.-600° C.) for a prolonged time to achieve the desired crystallinity of the TCO films can damage underlying layers, such as a flexible substrate and perovskite and/or organic thin films. Irradiation with a Xenon lamp cannot provide layer-specific annealing for TCO films either. TCO annealing with a Xenon lamp can cause overheating of an underlying layer because Xenon lamps provide a broad illumination spectrum with only a small portion of irradiation is in UV light range; The UV point beam laser can emit a strong UV beam with almost a single wavelength; however, it requires raster scanning over the film, which slows down the annealing process over large-area film thus less cost-effective. As stated above, the photonic annealing with the methods disclosed herein is able to attain a rapid and layer-specific treatment for the target TCO films. The absorbed irradiation of the photonic treatment directly provides energy for crystallization. With the peak wavelength for maximum UV light absorption of target TCO film and exponential decay of light intensity upon absorption, photonic annealing (e.g., UV-LED photonic annealing) can be concentrated on the chosen TCO film, resulting in layer-specific treatment. Also, the photonic treatment can result in a uniform TCO film quality over a large area because of an even distribution of radiation intensity. The rapid and layer-specific annealing and sintering for TCO films by using UV-LEDs are fully compatible with large-area high-speed printing, and thus the disclosed method herein can be integrated into high-speed printing to attain high-quality TCO films.

Accordingly, a need exists for improved methods for annealing and sintering transparent conductive oxides. These needs and other needs are at least partially satisfied by the present disclosure.

### SUMMARY

In accordance with the purposes of the disclosed materials, devices, and methods, as embodied and broadly described herein, the disclosed subject matter relates to methods of photonic annealing and/or sintering a transparent conductive oxide (TCO) film, comprising irradiating the TCO film with a light source, and wherein the photonic annealing and/or sintering is highly selective to the TCO film. It is understood that the methods disclosed herein allow annealing and/or sintering of the TOC films without damaging underlying layers, such as a flexible substrate and perovskite and/or organic thin films if present.

In certain aspects, the disclosed method is directed to TCO films comprising indium tin oxide film (ITO), fluorine-doped tin film (FTO), indium doped zinc oxide (IZO), or aluminum-doped zinc oxide (AZO).

In yet other aspects, the light source emits radiation comprising wavelengths within about 80 nm to about 5 nm of the wavelength of maximum absorbance (Amax) of the transparent conductive oxide (TCO) film.

In yet other aspects, the light source can comprise one or more of an array of ultraviolet light-emitting diodes (UV-LEDs), a UV light-emitting diode, a line-scanned UV laser, filtered UV lights obtained from any light source configured to irradiate UV light.

In yet further aspects, the light source used in the disclosed methods can emit radiation in a wavelength range from about 200 nm to about 400 nm.

Also disclosed herein are annealed transparent conductive oxide films prepared by the disclosed herein methods.

Also disclosed are devices that comprise these annealed transparent conductive oxide films. It is understood that in some aspects, such a device can comprise a solar cell. In yet other aspects, such a device can comprise a light-emitting diode. In still further aspects, the device can be a photodetector. While in other aspects, the device can be a laser diode.

Also disclosed are solar cells comprising annealed transparent conductive oxide films prepared by the disclosed methods.

In still further aspects, disclosed are light-emitting diodes comprising annealed transparent conductive oxide films prepared by the disclosed methods.

Also disclosed are photodetectors and laser diodes comprising annealed transparent conductive oxide films prepared by the disclosed methods.

Also disclosed herein is a method of photonic annealing and/or sintering a transparent conductive oxide (TCO) film, comprising irradiating the TCO film with a light source, wherein the light source emits radiation comprising wavelengths within about 70 nm to about 10 nm of the wavelength of maximum absorbance (Amax) of the transparent conductive oxide (TCO) film, wherein the light source comprises an array of ultraviolet light-emitting diodes (UV-LEDs) and wherein the photonic annealing and/or sintering is highly selective to the TCO film.

Additional advantages will be set forth in part in the description that follows and in part will be obvious from the description or may be learned by practice of the aspects described below. The advantages described below will be realized and attained by means of the elements and combinations particularly pointed out in the appended claims. It is understood that both the foregoing general description and the following detailed description are exemplary and explanatory only and are not restrictive.

### BRIEF DESCRIPTION OF DRAWINGS

FIG. 1 shows exemplary devices of solution-processed thin-film double-junction solar cells that can be formed by the methods disclosed herein in one aspect.

FIG. 2 shows exemplary devices of solution-processed thin-film bifacial tandem solar cells that can be formed by the methods disclosed herein in one aspect.

FIG. 3 shows exemplary top- and bottom-emitting organic or perovskite light-emitting diodes (LEDs) having an ITO film be annealed as disclosed herein in one aspect.

FIG. 4 shows the extinction coefficient of an exemplary transparent conductive oxide (ITO).

### DETAILED DESCRIPTION

The present invention can be understood more readily by reference to the following detailed description, examples, drawings, and claims, and their previous and following description. However, before the present articles, systems, and/or methods are disclosed and described, it is to be understood that this invention is not limited to the specific or exemplary aspects of articles, systems, and/or methods disclosed unless otherwise specified, as such can, of course, vary. It is also to be understood that the terminology used herein is for the purpose of describing particular aspects only and is not intended to be limiting.

The following description of the invention is provided as an enabling teaching of the invention in its best, currently known aspect. To this end, those skilled in the relevant art will recognize and appreciate that many changes can be made to the various aspects of the invention described herein while still obtaining the beneficial results of the present invention. It will also be apparent that some of the desired benefits of the present invention can be obtained by selecting some of the features of the present invention without utilizing other features. Accordingly, those of ordinary skill in the pertinent art will recognize that many modifications and adaptations to the present invention are possible and may even be desirable in certain circumstances and are a part of the present invention. Thus, the following description is again provided as illustrative of the principles of the present invention and not in limitation thereof.

### Definitions

As used herein, the singular forms “a,” “an,” and “the” include plural referents unless the context clearly dictates otherwise. Thus, for example, reference to a “solar cell” includes aspects having two or more such solar cells unless the context clearly indicates otherwise.

It is appreciated that certain features of the disclosure, which are, for clarity, described in the context of separate aspects, can also be provided in combination in a single aspect. Conversely, various features of the disclosure, which are, for brevity, described in the context of a single aspect, can also be provided separately or in any suitable subcombination.

As used herein, the terms “optional” or “optionally” mean that the subsequently described event or circumstance may or may not occur and that the description includes instances where said event or circumstance occurs and instances where it does not.

It is also to be understood that the terminology used herein is for the purpose of describing particular aspects only and is not intended to be limiting. As used in the specification and the claims, the term “comprising” can include the aspects “consisting of” and “consisting essentially of.” Unless defined otherwise, all technical and scientific terms used herein have the same meaning as commonly understood by one of ordinary skill in the art to which this invention belongs. In this specification and in the claims, which follow, reference will be made to a number of terms that shall be defined herein.

For the terms “for example” and “such as,” and grammatical equivalences thereof, the phrase “and without limitation” is understood to follow unless explicitly stated otherwise.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Furthermore, when numerical ranges of varying scope are set forth herein, it is contemplated that any combination of these values inclusive of the recited values may be used. Further, ranges can be expressed herein as from “about” one particular value and/or to “about” another particular value. When such a range is expressed, another aspect includes from the one particular value and/or to the other particular value.

Similarly, when values are expressed as approximations, by use of the antecedent “about,” it will be understood that the particular value forms another aspect. It will be further understood that the endpoints of each of the ranges are significant both in relation to the other endpoint and independently of the other endpoint. Unless stated otherwise, the term “about” means within 5% (e.g., within 2% or 1%) of the particular value modified by the term “about.”

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein, the term “and/or” includes any and all combinations of one or more of the associated listed items.

It will be understood that, although the terms “first,” “second,” etc., may be used herein to describe various elements, components, regions, layers, and/or sections. These elements, components, regions, layers, and/or sections should not be limited by these terms. These terms are only used to distinguish one element, component, region, layer, or section from another element, component, region, layer, or a section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s). It will be understood that the spatially relative terms are intended to encompass different orientations of the device in use or operation. For example, if the device described herein is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein interpreted accordingly.

As used herein, the term “substantially” means that the subsequently described event or circumstance completely occurs or that the subsequently described event or circumstance generally, typically, or approximately occurs.

Still further, the term “substantially” can in some aspects refer to at least about 80%, at least about 85%, at least about 90%, at least about 91%, at least about 92%, at least about 93%, at least about 94%, at least about 95%, at least about 96%, at least about 97%, at least about 98%, at least about 99%, or about 100% of the stated property, component, composition, or other condition for which substantially is used to characterize or otherwise quantify an amount.

In other aspects, as used herein, the term “substantially free,” when used in the context of a composition or component of a composition that is substantially absent, is intended to indicate that the recited component is not intentionally batched and added to the composition, but can be present as an impurity along with other components being added to the composition. In such aspects, the term “substantially free” is intended to refer to trace amounts that can be present in the batched components, for example, it can be present in an amount that is less than about 1% by weight, e.g., less than about 0.5% by weight, less than about 0.1% by weight, less than about 0.05% by weight, or less than about 0.01% by weight of the stated material, based on the total weight of the composition.

As used herein, the term “substantially,” in, for example, the context “substantially identical” or “substantially similar” refers to a method or a system, or a component that is at least about 90%, at least about 91%, at least about 92%, at least about 93%, at least about 94%, at least about 95%, at least about 96%, at least about 97%, at least about 98%, at least about 99%, or about 100% by similar to the method, system, or the component it is compared to.

As used herein, the term or phrase “effective,” “effective amount,” or “conditions effective to” refers to such amount or condition that is capable of performing the function or property for which an effective amount or condition is expressed. As will be pointed out below, the exact amount or particular condition required will vary from one aspect to another, depending on recognized variables such as the materials employed and the processing conditions observed. Thus, it is not always possible to specify an exact “effective amount” or “condition effective to.” However, it should be understood that an appropriate, effective amount will be readily determined by one of ordinary skill in the art using only routine experimentation.

As used herein, the term “highly selective,” refers to a method that is selective to a specific component over other possibly present components. For example, “highly selective” in a context of photonic annealing and/or sintering refers to a method that is at least about 50%, at least about 55%, at least about 60%, at least about 65%, at least about 70%, at least about 75%, at least about 80%, at least about 85%, at least about 90%, at least about 95%, at least about 100%, at least about 200%, at least about 300%, or about 500% more selective to the specified film when compared to other films that can be present in the described system or device.

While aspects of the present invention can be described and claimed in a particular statutory class, such as the system statutory class, this is for convenience only, and one of ordinary skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred in any respect. This holds for any possible non-express basis for interpretation, including matters of logic with respect to arrangement of steps or operational flow, plain meaning derived from grammatical organization or punctuation, or the number or type of aspects described in the specification.

The present invention may be understood more readily by reference to the following detailed description of various aspects of the invention.

The present disclosure relates to methods of annealing a transparent conductive oxide (TCO) film, comprising irradiating the TCO film with a light source. In such aspects, the photonic annealing and/or sintering is highly selective to the TCO film. In still further aspects, the light source emits radiation comprising wavelengths within about 80 nm to about 5 nm of the wavelength of maximum absorbance (Amax) of the transparent conductive oxide (TCO) film wherein the light source comprises an array of ultraviolet light-emitting diodes (UV-LEDs).

In some aspects, the light source emits radiation comprising wavelengths within about 80 nm, about 70 nm, about 65 nm, about 60 nm, about 55 nm, about 50 nm, about 45 nm, about 40 nm, about 35 nm, about 30 nm, or about 25 nm of the wavelength of maximum absorbance (λₘₐₓ) of the transparent conductive oxide (TCO) film and wherein the annealing is selective to the TCO film. In still further aspects, the TCO films of the current disclosure are illuminated with the light source that emits radiation comprising wavelengths within about 30 nm of the wavelength of maximum absorbance (λₘₐₓ) of the transparent conductive oxide (TCO) film.

In still further embodiments, the light source can emit radiation having a spectral width of about 30 nm or less, or about 25 nm or less, or about 20 nm or less, about 15 nm or less, or about 10 nm or less, or about 9 nm or less, about 8 nm or less, about 7 nm or less, about 6 nm or less, about 5 nm or less.

It is understood that if, for example, and without limitation, the (λₘₐₓ) of the transparent conductive oxide (TCO) film is about 250 nm, the light source can emit radiation, for example, within about 220-about 290 nm, or within about 230-about 280 nm, or within about 240-about 270 nm, or within about 250-about 260 nm, or within about 240-about 310 nm, or within about 250-about 320 nm. It is further understood that these values are exemplary and unlimiting.

The wavelength of light used will depend on the wavelength of the maximum absorption of a specific TCO film. Yet further, the light source can emit radiation in a wavelength range from about 200 nm to about 400 nm, including exemplary values of about 210 nm, about 220 nm, about 230 nm, about 240 nm, about 250 nm, about 260 nm, about 270 nm, about 280 nm, about 290 nm, about 300 nm, about 310 nm, about 320 nm, about 330 nm, about 340 nm, about 350 nm, about 360 nm, about 370 nm, about 380 nm, and about 390 nm. It is understood that the light source can emit radiation at any wavelength between any two disclosed above wavelengths.

In certain aspects, the annealing of the transparent conductive oxide films can also cause the sintering of these films. In still further aspects, the annealing and sintering of the TCOs films improve film crystallinity, thereby reducing sheet resistance without affecting the light transmission properties of the film.

In still further aspects, the TCO film can comprise any suitable material that can be used for contacts or interconnecting layers in tandem solar cells. In some exemplary and unlimiting aspects, the TCO film comprises an indium tin oxide film (ITO), a fluorine-doped tin oxide film (FTO), an indium-doped zinc oxide film (IZO), or an aluminum-doped zinc oxide film (AZO).

In still further aspects, the TCO films can also be doped with a suitable dopant. In some exemplary and unlimiting aspects, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (FI). In yet other exemplary aspects, SnO₂ can be doped with antimony (Sb), F, As, niobium (Nb), or tantalum (Ta). In other exemplary aspects, In₂O₃ can be doped with tin (Sn), Mo, Ta, tungsten (W), Zr, F, Ge, Nb, Hf, or Mg. In still further aspects, the TCO films disclosed herein can also comprise any known transparent conductive oxide materials and corresponding dopants that are suitable for specific applications.

It is understood that the initial (not annealed) TCO films can be prepared by any known solution-processing methods, including a roll-to-roll printing process or any combination thereof.

In still further aspects, the TCO films are formed by a solution-processing technique. While in other exemplary aspects, the TCO films are formed by a roll-to-roll printing process. In yet other aspects, the TCO films are formed by a roll-to-roll printing process for flexible devices.

In yet further aspects, the TCO films of the current invention can have an average thickness of about 10 nm to about 1,000 nm, including exemplary values of about 10 nm, about 25 nm, about 50 nm, about 75 nm, about 100 nm, about 125 nm, about 150 nm, about 175 nm, about 200 nm, about 225 nm, about 250 nm, about 275 nm, about 300 nm, about 325 nm, about 350 nm, about 375 nm, about 400 nm, about 425 nm, about 450 nm, about 475 nm, about 500 nm, about 525 nm, about 550 nm, about 575 nm, about 600 nm, about 625 nm, about 650 nm, about 675 nm, about 700 nm, about 725 nm, about 750 nm, about 775 nm, about 800 nm, about 825 nm, about 850 nm, about 875 nm, about 900 nm, about 925 nm, about 950 nm, and about 975 nm. It is understood, however, the transparent conductive oxide films disclosed herein can have any thickness between any two disclosed thicknesses.

It is also understood that the disclosed herein TCO films can be formed on any known in the art substrates. In certain aspects, the disclosed TCO films are formed on flexible substrates. In yet other aspects, the TCO films can be formed on glass substrates.

In still further aspects, the disclosed herein transparent conductive oxide thin films can exhibit a high extinction coefficient in the UV range of the electromagnetic spectrum. In some aspects, the TCOs films have a wavelength of maximum absorbance (λₘₐₓ) of 400 nm or less, less than about 375 nm, less than about 350 nm, less than about 325 nm, about 300 nm or less, less than about 300 nm, less than about 275 nm, from about 200 nm to about 350 nm, from about 250 nm to about 350 nm, from about 200 nm to about 325 nm, from about 200 nm to about 310 nm, from about 200 nm to about 300 nm or from about 250 nm to about 300 nm.

Still, further, the methods disclosed herein comprise steps of irradiating of the TCO films with the light source for annealing purposes for a total amount of time from about 1 millisecond to about 5 minutes, including exemplary values of about 5 ms, about 10 ms, about 20 ms, about 30 ms, about 40 ms, about 50 ms, about 75 ms, about 100 ms, about 125 ms, about 150 ms, about 200 ms, about 250 ms, about 300 ms, about 400 ms, about 500 ms, about 750 ms, about 1 second, about 5 seconds, about 10 seconds, about 20 seconds, about 30 seconds, about 40 seconds, about 50 seconds, about 1 minute, about 2 minutes, about 3 minutes, and about 4 minutes, depending on the intensity of the irradiation. It is understood that a specific time frame can be chosen depending on the power intensity of UV light sources.

In still further aspects, the TCO film can be continuously irradiated for a total amount of about 5 minutes or less, about 4 minutes, about 3 minutes, about 2 minutes, about 1 minute, about 50 seconds or less, about 40 seconds or less, about 30 seconds or less, about 20 seconds or less, about 10 seconds or less, about 5 seconds or less, about 1 second or less, about 750 milliseconds (ms) or less, about 500 ms or less, about 400 ms or less, about 300 ms or less, about 250 ms or less, about 200 ms or less, about 150 ms or less, about 125 ms or less, about 100 ms or less, about 75 ms or less, about 50 ms or less, about 40 ms or less, about 30 ms or less, about 20 ms or less, or about 10 ms or less, depending on the power intensity of the irradiation.

In certain aspects, the irradiation of the TCOs films for annealing purposes can be done with a constant emission of the light for the desired period of time. Yet, in other aspects, the light source can emit pulsed radiation. In such aspects, the TCO film can be irradiated by a plurality of pulses. If the plurality of pulses of the light emitted from the light source is used, such pulses can have each of the plurality of pulses has the same or different duration. In some exemplary aspects, wherein each pulse is from about 1 millisecond to less than about 1 minute, including exemplary values of about 5 ms, about 10 ms, about 20 ms, about 30 ms, about 40 ms, about 50 ms, about 75 ms, about 100 ms, about 125 ms, about 150 ms, about 200 ms, about 250 ms, about 300 ms, about 400 ms, about 500 ms, about 750 ms, about 1 second, about 5 seconds, about 10 seconds, about 20 seconds, about 30 seconds, about 40 seconds, and about 50 seconds, depending on the power intensity of the irradiation.

It is understood that any light source capable of producing the above radiation can be utilized. In some aspects, the light source is designed to emit light only in the UV range of the light spectra, such as, for example, and without limitations, one or more of an array of ultraviolet light-emitting diodes (UV-LEDs), a UV light-emitting diode, a line-scanned UV laser, filtered UV lights obtained from any light source configured to irradiate UV light. In yet other aspects, the light source can comprise UV light that is obtained by applying the desired filter to a broad spectra light source, for example, and without limitations, the broad spectra light sources can comprise Xenon lamp, mercury-vapor lamps, or metal-halide lamps, or any combination thereof. It is understood that the specific wavelength range of UV light can be chosen depending on the maximum absorption wavelength of a specific TCO film to be annealed. In yet other aspects, the light source is an array of ultraviolet light-emitting diodes.

In certain aspects, the UV-LED can provide peak irradiance between about 0.1 W/cm² to about 25 W/cm², including exemplary values of about 0.5 W/cm², about 1 W/cm², about 2 W/cm², about 3 W/cm², about 4 W/cm², about 5 W/cm², about 6 W/cm², about 7 W/cm², about 8 W/cm², about 9 W/cm², about 10 W/cm², about 11 W/cm², about 12 W/cm², about 13 W/cm², about 14 W/cm², about 15 W/cm², about 16 W/cm², about 17 W/cm², about 18 W/cm², about 19 W/cm², about 20 W/cm², about 21 W/cm², about 22 W/cm², about 23 W/cm², and about 24 W/cm². It is understood that in other aspects, the UV-LED can provide peak irradiance higher than about 25 W/cm².

Without wishing to be bound by any theory, it is understood that the light intensity (power in the unit area) affects the annealing time to attain high-quality film. The higher the light source intensity, the shorter the annealing time is. Individual LEDs can be closely or loosely packed, the overall power per unit area (light intensity) determines the annealing time and film quality.

Also disclosed herein are the annealed transparent conductive films prepared by the disclosed methods.

In certain aspects, also disclosed are devices comprising such TCO thin films. In certain aspects, the device can be a flexible device. In yet other aspects, the device can be a solar cell or a light-emitting diode. In yet still further aspects, the device can be a photodetector. While in still further aspects, the device can be a laser diode.

In certain aspects, disclosed are solar cells comprising the TCO thin films prepared by the disclosed methods. Such solar cells can be four-terminal or two-terminal tandem cells or bi-facial solar cells.

In certain aspects, the solar cell can be any solar cell known in the art. Yet, in some other aspects, the solar cell comprises one or more perovskite solar cells, organic solar cell, copper indium gallium selenide solar cell (CIGS), and cadmium telluride (CdTe), or silicon solar cell.

It is understood that the annealed TCO film disclosed herein can serve as a contact layer or as an interconnect layer, or directly on the top of a flexible substrate, depending on the specific cell disclosed herein.

In some aspects, the annealed TCO film is a top electrode configured to be illuminated with light. It is understood that the present methods substantially eliminate a need for the use of a hot plate to anneal the film. It is further understood that since the UV light source can be chosen to irradiate the TCO film at a specific wavelength that is specific to this TCO film for maximum light absorption, such an annealing process is layer-specific and will not affect any of the layers that are underlaying the TCO film.

As disclosed above, for photonic treatment, the light source power and pulse width can be precisely controlled and manipulated. This feature facilitates identifying the energy required for the transparent conductive oxide film to achieve high-quality film through rapid and layer-specific UV annealing while also avoiding supplying excess energy that can affect underlying films.

In yet further aspects, the annealed TCO film can be an anode and/or cathode, depending on the desired application.

In yet further aspects, the device disclosed herein, either the solar cell or the light-emitting diode, such a device can also comprise two or more TCO films. For example, and without limitation, the solar cell and/or light-emitting diode can further comprise a second annealed TCO film that is the same or different from the annealed TCO film.

In certain aspects, this second TCO film can be a bottom electrode or an interconnecting layer between two subcells in a tandem cell configuration. The second TCO film can also be either anode or cathode, depending on the desired application. The second TCO film can be any of the disclosed above TCO films. For example, and without limitations, the TCO film can comprise indium tin oxide film (ITO), fluorine-doped tin film (FTO), indium doped zinc oxide (IZO), or aluminum-doped zinc oxide (AZO).

In yet other aspects, the second TCO film can be formed by a solution-processing technique, including a roll-to-roll printing process or any combination thereof.

In still further aspects, the second TCO film is a bottom electrode disposed directly on top of a flexible substrate. In such aspects, the annealing of the second TCO film has to be selective for the second TCO film because typical flexible substrates cannot withstand high temperatures. Therefore the second TCO has to be annealed using UV-light as disclosed herein.

In still further aspects, when the second TCO film is a bottom electrode directly on top of a glass substrate, such a TCO film can be annealed by any known in the art methods. While it can be annealed using UV-light as disclosed herein, since only glass is present under the bottom electrode, there is no expectation of adverse effects if a conventional hot plate annealing is utilized. In such aspects, the annealing of the second TCO film does not have to be selective for the second TCO film.

In still further aspects, the disclosed herein devices can comprise the light-emitting diodes. Such LED devices can also comprise a perovskite-based light-emitting diode or an organic light-emitting diode. Similar to the solar cells, the annealed TCO can be a top or a bottom electrode or interconnecting layer. In yet other aspects, the devices disclosed herein can comprise photodetectors and/or laser diodes.

### Examples

The following examples are put forth so as to provide those of ordinary skill in the art with a complete disclosure and description of how the compounds, compositions, articles, devices, and/or methods claimed herein are made and evaluated and are intended to be purely exemplary and are not intended to limit the disclosure.

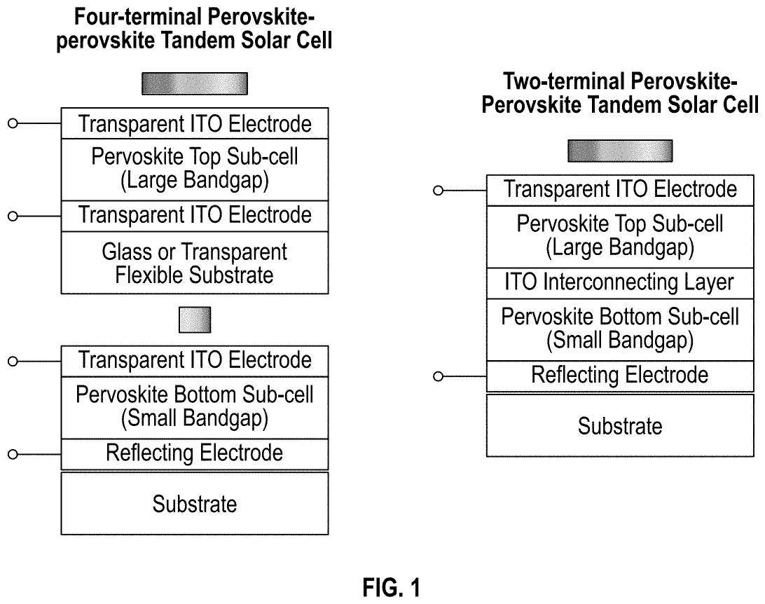

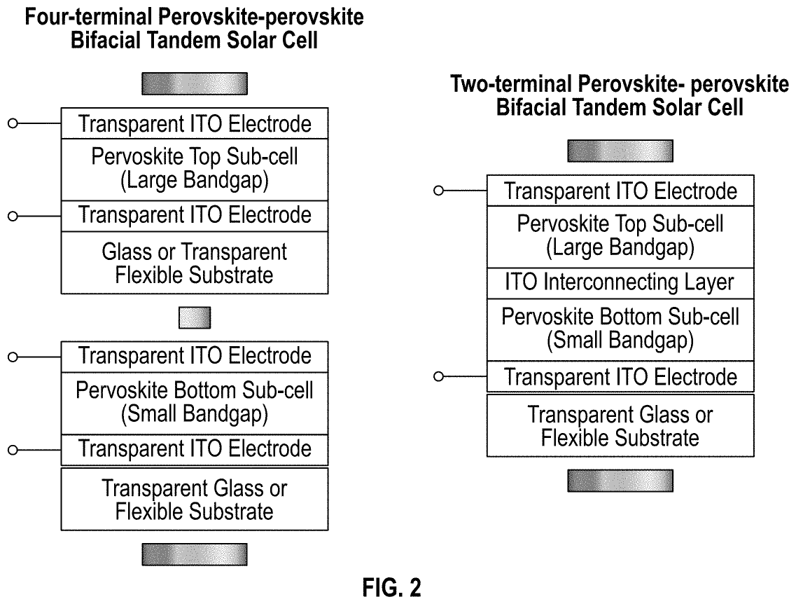

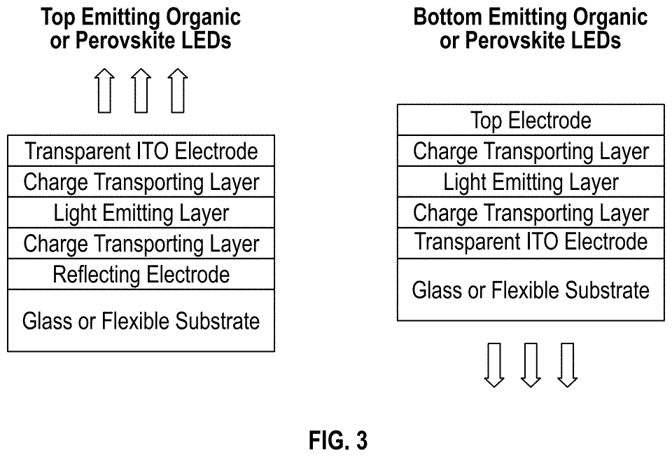

FIGS. 1, 2, and 3 show exemplary devices that can be prepared by the disclosed herein methods. For example, FIG. 1 shows exemplary four- and two-terminal perovskite tandem solar cells having an exemplary transparent ITO that can be annealed by the methods disclosed herein. FIG. 2 shows exemplary four- and two-terminal perovskite bifacial tandem solar cells having an exemplary transparent ITO that can be annealed by the methods disclosed herein. FIG. 3 shows exemplary top- and bottom-emitting organic or perovskite LEDs having an ITO film be annealed as described herein. The disclosed herein annealing methods would prevent damage to the underlying layers such as the perovskite layer or charge-transporting layers, or light-emitting layers, for example.

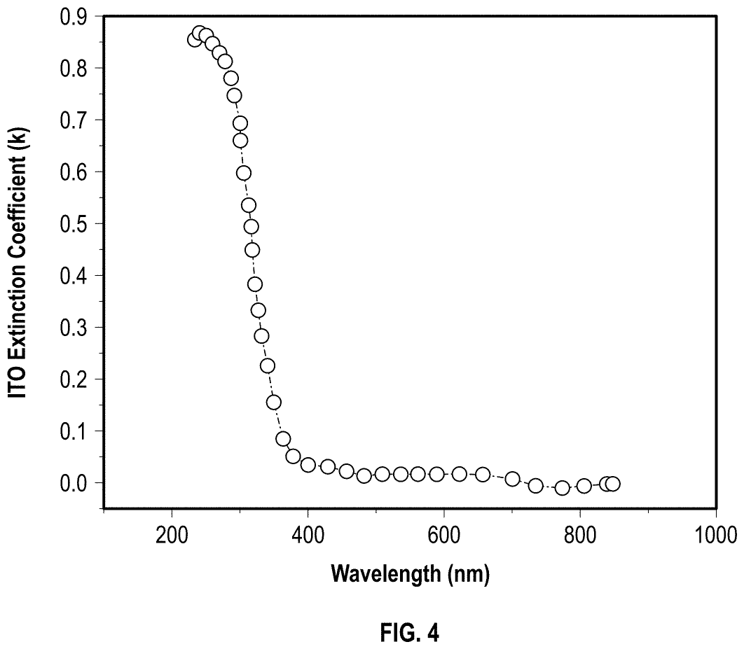

FIG. 4 shows the ITO extinction coefficient as a function of wavelengths. For example, the maximum absorption of ITO is about 270 nm. The UV-LED sources, for example, and without limitation, can provide wavelengths with a spectrum as narrow as 10 nm for peak absorption. This strong photon absorption and exponential decal of light intensity in the aiming TCO film could concentrate energy supply on a single layer leading to layer-specific photonic annealing.

What is claimed is:

1. A method of photonic annealing and/or sintering a transparent conductive oxide (TCO) film, comprising irradiating the TCO film with a light source, and wherein the photonic annealing and/or sintering is highly selective to the TCO film.

2. The method of claim 1, wherein the annealed TCO film is sintered.

3. The method of claim 1, wherein the TCO film comprises indium tin oxide film (ITO), fluorine-doped tin film (FTO), indium doped zinc oxide (IZO), or aluminum-doped zinc oxide (AZO).

4. The method of claim 1, wherein the TCO film is formed by a solution processing technique or roll-to-roll printing process.

5. The method of claim 1, wherein the light source emits radiation comprising wavelengths within about 80 nm to about 5 nm of the wavelength of maximum absorbance (λₘₐₓ) of the transparent conductive oxide (TCO) film.

6. The method of claim 1, wherein the light source emits radiation in a wavelength range from about 200 nm to about 400 nm.

7. The method of claim 1, wherein the TCO film is irradiated for a total amount of time from about 1 millisecond to about 5 minutes.

8. The method of claim 1, wherein the TCO film is continuously irradiated for about 5 minutes or less, about 3 minutes or less, about 1 minute or less, about 30 seconds or less, or about 10 seconds or less.

9. The method of claim 1, wherein the light source emits pulsed radiation, and the step of irradiating the TCO film comprises applying a plurality of pulses.

10. The method of claim 9, wherein each of the plurality of pulses has the same or different duration.

11. The method of claim 9, wherein each pulse is from about 1 millisecond to less than about 1 minute.

12. The method of claim 1, wherein the light source comprises one or more of an array of ultraviolet light-emitting diodes (UV-LEDs), a UV light-emitting diode, a line-scanned UV laser, filtered UV lights obtained from any light source configured to irradiate UV light.

13. The method of claim 1, wherein the array of the UV-light emitting diodes provides light intensity between about 0.1 W/cm² to about 25 W/cm².

14. The method of claim 1, wherein the TCO film has an average thickness of about 10 nm to about 1,000 nm.

15. An annealed transparent conductive oxide (TCO) film prepared by the method of claim 1.

16. A device comprising the annealed and/or sintered TCO film of claim 15.

17. The device of claim 16, wherein the device is a flexible or a rigid thin-film device.

18. The device of claim 16, wherein the device is a solar cell further comprising further one or more TCO films that are the same or different from the annealed and/or sintered TCO film.

19. The solar cell of claim 18, wherein the solar cell is a four-terminal or a two-terminal tandem cell, or a bi-facial solar cell.

20. The solar cell of claim 18, wherein the solar cell comprises one or more of perovskite solar cell, organic solar cell, copper indium gallium selenide solar cell (CIGS), cadmium telluride (CdTe), or silicon solar cell.

21. The solar cell of claim 18, wherein the annealed and/or sintered TCO film is a top electrode and/or a bottom electrode and/or interconnecting layer configured to allow light transmission.

22. The solar cell of claim 18, wherein the annealed and/or sintered TCO film is an anode and/or cathode and/or recombination layer (interconnecting layer).

23. The device of claim 16, wherein the device is a light-emitting diode, in which the annealed and/or sintered TCO film is a top or a bottom electrode.

24. The light-emitting diode of claim 23, wherein the light-emitting diode comprises a perovskite-based light-emitting diode or an organic light-emitting diode.

25. A method of photonic annealing and/or sintering a transparent conductive oxide (TCO) film, comprising irradiating the TCO film with a light source, wherein the light source emits radiation comprising wavelengths within about 80 nm to about 5 nm of the wavelength of maximum absorbance (λₘₐₓ) of the transparent conductive oxide (TCO) film, wherein the light source comprises an array of ultraviolet light-emitting diodes (UV-LEDs) and wherein the photonic annealing and/or sintering is highly selective to the TCO film.
